(19) United States
(12) Patent Application Publication
(10) Pub. No.: US 2016/0211207 A1
(43) Pub. Date: Jul. 21, 2016

(54) SEMICONDUCTOR ASSEMBLY HAVING WIRING BOARD WITH ELECTRICAL ISOLATOR AND MOISTURE INHIBITING CAP INCORPORATED THEREIN AND METHOD OF MAKING WIRING BOARD

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/080,427

(22) Filed: Mar. 24, 2016

Related U.S. Application Data
(63) Continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015.
(60) Provisional application No. 61/949,652, filed on Mar. 7, 2014.

(51) Int. Cl. H01L 23/498; H01L 23/00; H01L 21/48; H01L 23/367

(52) U.S. Cl. CPC H01L 23/49838; H01L 23/3675; H01L 23/564; H01L 21/4846; H01L 21/4882

(57) ABSTRACT

A method of making a wiring board is characterized by the provision of moisture inhibiting caps covering interfaces between an electrical isolator/optional metal posts and a surrounding plastic material. In a preferred embodiment, the electrical isolator and metal posts are bonded to the resin core by an adhesive substantially coplanar with the metal layers on two opposite sides of the resin core, the metal posts and a thermally conductive slug that includes the electrical isolator at smoothed lapped top and bottom surfaces, so that a metal bridge can be deposited on the adhesive at the smoothed lapped bottom surface to completely cover interfaces between the electrical isolator/metal posts and the surrounding plastic material. Conductive traces are also deposited on the smoothed lapped top surface to provide electrical contacts for chip connection and electrically coupled to the metal posts.

### CROSS REFERENCE TO RELATED APPLICATIONS

This application is a continuation-in-part of U.S. application Ser. No. 14/621,332 filed Feb. 12, 2015 and a continuation-in-part of U.S. application Ser. No. 14/846,987 filed Sep. 7, 2015, each of which is hereby incorporated by reference.

### FIELD OF THE INVENTION

The present invention relates to a semiconductor assembly and, more particularly, to a semiconductor assembly having a wiring board with an electrical isolator incorporated in a resin core and a moisture inhibiting cap covering CTE mismatched interfaces, and a method of making the wiring board.

### DESCRIPTION OF RELATED ART

High voltage or high current applications such as power module or light emitting diode (LED) often require high performance wiring board for signal interconnection. However, as the power increases, large amount of heat generated by semiconductor chip would degrade device performance and impose thermal stress on the chip. Ceramic material, such as alumina or aluminum nitride which is thermally conductive, electrically insulative and low CTE (Coefficient of Thermal Expansion), is often considered as a suitable material for such kind of applications. U.S. Pat. Nos. 8,895,998 and 7,670,872 disclose various interconnect structures using ceramic as chip attachment pad material for better reliability. In addition, for applications where signal routing is in vertical direction, electrically conductive material such as metal post is also needed in the resin board for transmitting electricity. However, when two materials with different CTEs are embedded in resin board and the contact areas of ceramic/resin and metal/resin are small, the interfaces between them are prone to crack or delamination during thermal cycling, making this type of circuit board prohibitively unreliable for practical usage, because large amount of moisture may leak through the cracked interfaces and damage the assembled chip.

### SUMMARY OF THE INVENTION

A primary objective of the present invention is to provide a wiring board having at least one moisture inhibiting cap covering interfaces between two CTE-mismatched materials so as to prevent passage of moisture through cracks at the interfaces caused by mismatched CTE, thereby improving the reliability of the semiconductor assembly.

Another objective of the present invention is to provide a wiring board having a low CTE electrical isolator embedded in a resin core so as to resolve the chip/board CTE mismatch problem, thereby improving the mechanical reliability of the semiconductor assembly.

Yet another objective of the present invention is to provide a wiring board in which routing circuitries on the electrical isolator extend to the resin core, thereby allowing fine pitch assemblies such as flip chip to be assembled on the electrical isolator and interconnected to the external environment through electrical contacts on the resin core.

In accordance with the foregoing and other objectives, the present invention provides a wiring board having an electrical isolator, a resin core, a moisture inhibiting cap and conductive traces. The electrical isolator provides CTE-compensated contact interface for a semiconductor chip, and also provides primary heat conduction for the chip so that the heat generated by the chip can be conducted away. The resin core, which provides mechanical support for the electrical isolator, the moisture inhibiting cap and the conductive traces, serves as a spacer between the conductive traces and the moisture inhibiting cap. The moisture inhibiting cap, which laterally extend from the electrical isolator to the resin core, seal interfaces between the electrical isolator and a surrounding plastic material and serve as a moisture barrier to prevent passage of moisture through cracks at the interfaces. The conductive traces, disposed on the top sides of the electrical isolator and the resin core, provide signal horizontal transmission and electrical routing of the board. Optionally, the wiring board may further include metal posts and additional moisture inhibiting caps. The metal posts, laterally surrounded by the resin core, provide signal vertical transmission or ground/power plane for power delivery and return. The additional moisture inhibiting caps laterally extend from the metal posts to the resin core and seal interfaces between the metal posts and the surrounding plastic material.

In another aspect, the present invention provides a method of making a wiring board, comprising the steps of: providing an electrical isolator having planar top and bottom sides; providing a stacking structure that includes top and bottom metal layers, a binding film disposed between the top and bottom metal layers, and an aperture extending through the top metal layer, the binding film and the bottom metal layer, wherein the top and bottom metal layers each have a planar outer surface; inserting the electrical isolator into the aperture of the stacking structure leaving a gap between the stacking structure and the electrical isolator, and then squeezing and curing the binding film to form a resin core that has a top side bonded to the top metal layer and a bottom side bonded to the bottom metal layer, wherein the stacking structure is adhered to sidewalls of the electrical isolator by an adhesive squeezed out from the binding film into the gap between the stacking structure and the electrical isolator; removing an excess portion of the squeezed out adhesive, thereby the adhesive having exposed top and bottom surfaces substantially coplanar with the top and bottom sides of the electrical isolator and the outer surfaces of the top and bottom metal layers; forming conductive traces that includes contact pads and routing circuitries, wherein the contact pads laterally extend on the top side of the electrical isolator, and the routing circuitries laterally extend from the contact pads onto the resin core; and forming a moisture inhibiting cap that laterally extends from the bottom side of the electrical isolator to the bottom metal layer to completely cover the exposed bottom surface of the adhesive.

In yet another aspect, another method of making a wiring board comprises the steps of: providing a thermally conductive slug having planar top and bottom sides, wherein the thermally conductive slug includes an electrical isolator; providing metal posts each having planar top and bottom sides; providing a stacking structure that includes top and bottom metal layers, a binding film disposed between the top and bottom metal layers, a first aperture, and second apertures extending through the top metal layer, the binding film and the bottom metal layer, wherein the top and bottom metal layers each have a planar outer surface; inserting the thermally conductive slug into the first aperture of the stacking structure and the metal posts into the second apertures of the stacking structure leaving gaps between the stacking structure and the thermally conductive slug and between the stacking structure and the metal posts, and then squeezing and curing the binding film to form a resin core that has a top side bonded to the top metal layer and a bottom side bonded to the bottom metal layer, wherein the stacking structure is adhered to sidewalls of the thermally conductive slug and the metal posts by an adhesive squeezed out from the binding film into the gaps between the stacking structure and the thermally conductive slug and between the stacking structure and the metal posts; removing an excess portion of the squeezed out adhesive, thereby the adhesive having exposed top and bottom surfaces substantially coplanar with the top and bottom sides of the thermally conductive slug, the outer surfaces of the top and bottom metal layers, and the top and bottom sides of the metal posts; forming conductive traces that includes contact pads and routing circuitries, wherein the contact pads laterally extend on a top side of the electrical isolator, and the routing circuitries laterally extend from the contact pads onto the resin core and electrically connect the contact pads and the metal posts; and forming moisture inhibiting caps that laterally extend from a bottom side of the electrical isolator to the bottom metal layer, and laterally extend from the bottom side of the metal posts to the bottom metal layer to completely cover the exposed bottom surface of the adhesive.

Unless specifically indicated or using the term “then” between steps, or steps necessarily occurring in a certain order, the sequence of the above-mentioned steps is not limited to that set forth above and may be changed or reordered according to desired design.

The method of making a wiring board according to the present invention has numerous advantages. For instance, depositing the moisture inhibiting caps to seal interfaces between the electrical isolator and the surrounding plastic material and between the optional metal posts and the surrounding plastic material can establish moisture barriers so that the moisture inhibiting caps can prevent moisture through cracks at the interfaces from ambiance into the interior of the semiconductor assembly, thereby improving the reliability of the assembly. Binding the resin core to the electrical isolator and the optional metal posts can provide a platform for high resolution circuitries disposed thereon, thereby allowing fine pitch assemblies such as flip chip and surface mount component to be assembled on the board.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a thermally conductive slug in accordance with the first embodiment of the present invention;

FIG. 2 is a partial cross-sectional view of a stacking structure on a carrier film in accordance with the first embodiment of the present invention;

FIG. 3 is a partial cross-sectional view showing that the thermally conductive slug of FIG. 1 and metal posts are attached to the carrier film of FIG. 2 in accordance with the first embodiment of the present invention;

FIG. 4 is a partial cross-sectional view showing that the stacking structure of FIG. 3 is subjected to a lamination process in accordance with the first embodiment of the present invention;

FIG. 5 is a partial cross-sectional view showing that excess adhesive is removed from the structure of FIG. 4 in accordance with the first embodiment of the present invention;

FIG. 6 is a partial cross-sectional view showing that the carrier film is removed from the structure of FIG. 5 in accordance with the first embodiment of the present invention;

FIGS. 7, 8 and 9 are partial cross-sectional, bottom and top perspective views, respectively, showing that the structure of FIG. 6 is provided with moisture inhibiting caps and conductive traces to finish the fabrication of a wiring board in accordance with the first embodiment of the present invention;

FIG. 10 is a cross-sectional view of a semiconductor assembly with a chip electrically connected to the wiring board of FIG. 9 in accordance with the first embodiment of the present invention;

FIG. 11 is a partial cross-sectional view of a stacking structure on a carrier film in accordance with the second embodiment of the present invention;

FIG. 12 is a partial cross-sectional view showing that the thermally conductive slug of FIG. 1 and metal posts are attached to the carrier film of FIG. 11 in accordance with the second embodiment of the present invention;

FIG. 13 is a partial cross-sectional view showing that the stacking structure of FIG. 12 is subjected to a lamination process in accordance with the second embodiment of the present invention;

FIG. 14 is a partial cross-sectional view showing that excess adhesive and the carrier film are removed from the structure of FIG. 13 in accordance with the second embodiment of the present invention;

FIG. 15 is a partial cross-sectional view showing that the structure of FIG. 14 is provided with moisture inhibiting caps and conductive traces to finish the fabrication of a wiring board in accordance with the second embodiment of the present invention;

FIG. 16 is a partial cross-sectional view showing that an electrical isolator, metal posts and a stacking structure are attached to a carrier film in accordance with the third embodiment of the present invention;

FIG. 17 is a partial cross-sectional view showing that the stacking structure of FIG. 16 is subjected to a lamination process in accordance with the third embodiment of the present invention;

FIG. 18 is a partial cross-sectional view showing that excess adhesive is removed from the structure of FIG. 17 in accordance with the third embodiment of the present invention;

FIG. 19 is a partial cross-sectional view showing that the carrier film is removed from the structure of FIG. 18 in accordance with the third embodiment of the present invention;

FIG. 20 is a partial cross-sectional view showing that the structure of FIG. 19 is provided with moisture inhibiting caps and conductive traces to finish the fabrication of a wiring board in accordance with the third embodiment of the present invention;

FIG. 21 is a partial cross-sectional view of a stacking structure on a carrier film in accordance with the fourth embodiment of the present invention;

FIG. 22 is a partial cross-sectional view showing that an electrical isolator is attached to the carrier film of FIG. 21 in accordance with the fourth embodiment of the present invention;

FIG. 23 is a partial cross-sectional view showing that the stacking structure of FIG. 22 is subjected to a lamination process in accordance with the fourth embodiment of the present invention;

FIG. 24 is a partial cross-sectional view showing that excess adhesive and the carrier film are removed from the structure of FIG. 23 in accordance with the fourth embodiment of the present invention; and

FIG. 25 is a partial cross-sectional view showing that the structure of FIG. 24 is provided with a moisture inhibiting cap and conductive traces to finish the fabrication of a wiring board in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

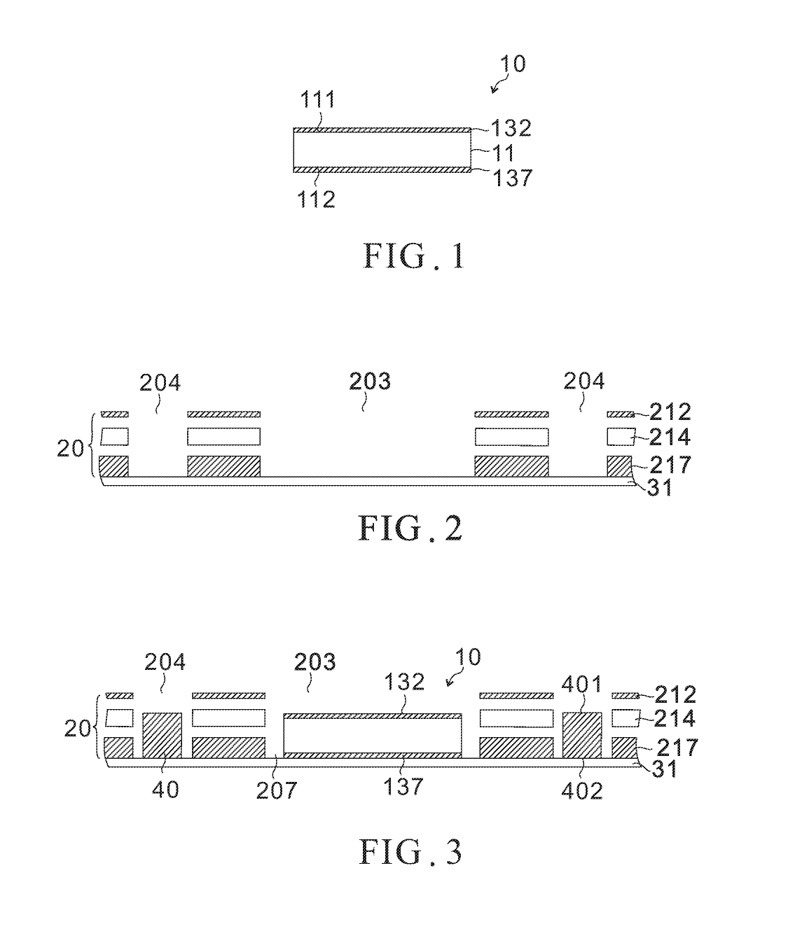

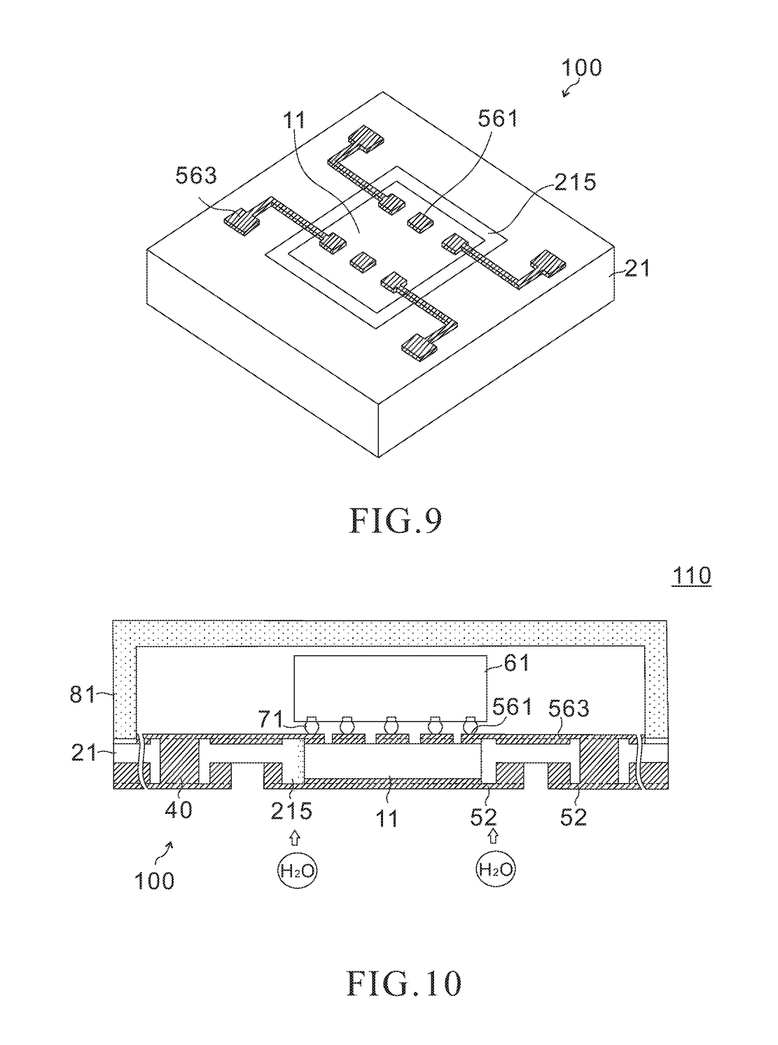

FIGS. 1-9 are schematic views showing a method of making a wiring board that includes an electrical isolator, metal posts, a resin core, moisture inhibiting caps and conductive traces in accordance with the first embodiment of the present invention.

FIG. 1 is a cross-sectional view of a thermally conductive slug 10 having a top metal film 132 and a bottom metal film 137 respectively deposited on planar top and bottom sides 111, 112 of an electrical isolator 11. The electrical isolator 11 typically has high elastic modulus and low coefficient of thermal expansion (for example, 2×10⁻⁶ K⁻¹ to 10×10⁻⁶ K⁻¹), such as ceramic, silicon, glass or other thermally conductive and electrically insulating materials. In this embodiment, the electrical isolator 11 is a ceramic plate of 0.4 mm in thickness. The top metal film 132 and the bottom metal film 137 each have a planar outer surface and are typically made of copper and each have a thickness of 35 microns.

FIG. 2 is a partial cross-sectional view of a stacking structure 20 having first and second apertures 203, 204 on a carrier film 31. The stacking structure 20 includes a top metal layer 212, a binding film 214 and a bottom metal layer 217. The first and second apertures 203, 204 are formed by punching through the top metal layer 212, the binding film 214 and the bottom metal layer 217. Also, the first and second apertures 203, 204 may be formed by other techniques such as laser cutting with or without wet etching. The carrier film 31 typically is a tape, and the bottom metal layer 217 is attached to the carrier film 31 by the adhesive property of the carrier film 31. In this stacking structure 20, the binding film 214 is disposed between the top metal layer 212 and the bottom metal layer 217. The top metal layer 212 and the bottom metal layer 217 are typically made of copper and each have two opposite planar surfaces facing towards the upward and downward directions, respectively. The binding film 214 can be various dielectric films or prepregs formed from numerous organic or inorganic electrical insulators. For instance, the binding film 214 can initially be a prepreg in which thermosetting epoxy in resin form impregnates a reinforcement and is partially cured to an intermediate stage. The epoxy can be FR-4 although other epoxies such as polyfunctional and bismaleimide triazine (BT) are suitable. For specific applications, cyanate esters, polyimide and PTFE are also suitable. The reinforcement can be E-glass although other reinforcements such as S-glass, D-glass, quartz, kevlar aramid and paper are suitable. The reinforcement can also be woven, non-woven or random microfiber. A filler such as silica (powdered fused quartz) can be added to the prepreg to improve thermal conductivity, thermal shock resistance and thermal expansion matching Commercially available prepregs such as SPEEDBOARD C prepreg by W.L. Gore & Associates of Eau Claire, Wis. are suitable. In this embodiment, the binding film 214 is a prepreg with B-stage uncured epoxy provided as a non-solidified sheet, and the top metal layer 212 and the bottom metal layer 217 are copper layers of 0.025 mm and 0.2 mm in thickness, respectively.

FIG. 3 is a partial cross-sectional view of the structure with the thermally conductive slug 10 of FIG. 1 and metal posts 40 attached on the carrier film 31. The thermally conductive slug 10 is inserted into the first aperture 203 of the stacking structure 20, whereas the metal posts 40 are inserted into the second apertures 204 of the stacking structure 20. The metal posts 40 each have opposite planar top and bottom sides 401, 402, and can be made of any electrically conductive material. In this embodiment, the metal posts 40 are copper posts each having a thickness substantially equal to that of the thermally conductive slug 10. The thermally conductive slug 10 and the metal posts 40 are attached on the carrier film 31 with the outer surface of the bottom metal film 137 and the bottom side 402 of the metal posts 40 facing towards the carrier film 31 without contacting the stacking structure 20. As a result, gaps 207 are located in the first and second apertures 203, 204 between the thermally conductive slug 10 and the stacking structure 20 and between the metal posts 40 and the stacking structure 20. The gaps 207 laterally surround the thermally conductive slug 10 and the metal posts 40 and are laterally surrounded by the stacking structure 20. In this illustration, the thermally conductive slug 10 and the metal posts 40 are attached to the carrier film 31 by the adhesive property of the carrier film 31. Also, the thermally conductive slug 10 and the metal posts 40 may be attached to the carrier film 31 by dispensing extra adhesive.

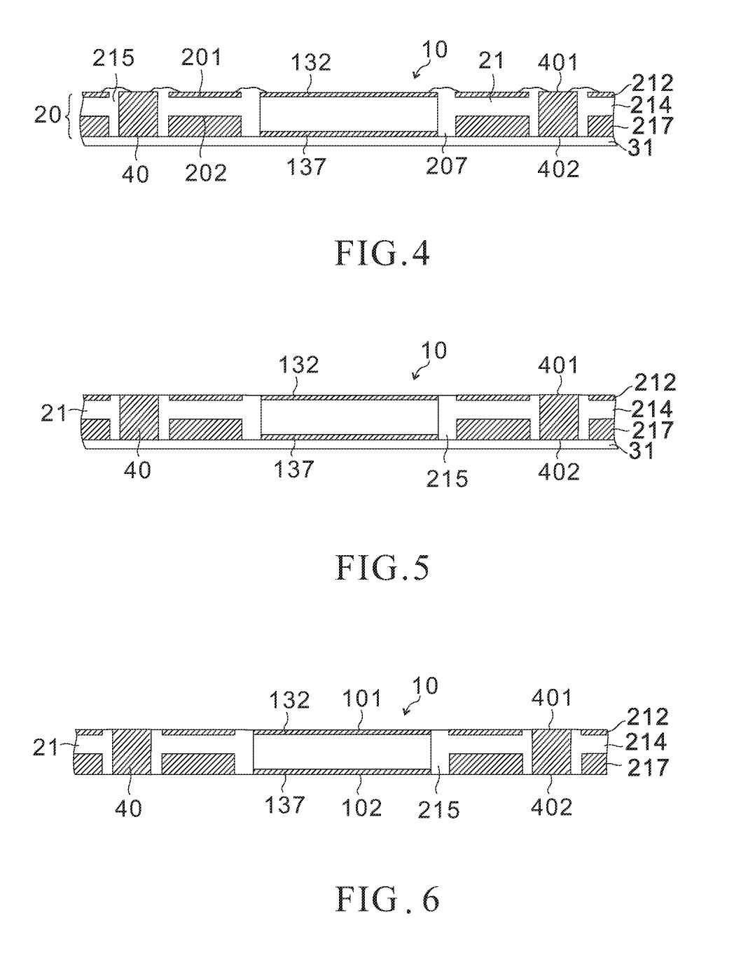

FIG. 4 is a partial cross-sectional view of the structure in which the gaps 207 are filled with an adhesive 215 squeezed out from the binding film 214. By applying heat and pressure, the binding film 214 is squeezed and part of the adhesive in the binding film 214 flows into the gaps 207. The bonding film 214 is compressed by applying downward pressure to the top metal layer 212 and/or upward pressure to the carrier film 31, thereby moving the top metal layer 212 and the bottom metal layer 217 towards one another and applying pressure to the binding film 214 while simultaneously applying heat to the binding film 214. The binding film 214 becomes compliant enough under the heat and pressure to conform to virtually any shape. As a result, the binding film 214 sandwiched between the top metal layer 212 and the bottom metal layer 217 is compressed, forced out of its original shape and flows into the gaps 207. The top metal layer 212 and the bottom metal layer 217 continue to move towards one another, and the binding film 214 remains sandwiched between and continues to fill the reduced space between the top metal layer 212 and the bottom metal layer 217. Meanwhile, the adhesive 215 squeezed out from the binding film 214 fills the gaps 207. In this illustration, the adhesive 215 squeezed out from the binding film 214 also rises slightly above the first and second apertures 203, 204 and overflows onto the top surfaces of the thermally conductive slug 10, the metal posts 40 and the top metal layer 212. This may occur due to the binding film 214 being slightly thicker than necessary. As a result, the adhesive 215 squeezed out from the binding film 214 creates a thin coating on the top surfaces of the thermally conductive slug 10, the metal posts 40 and the top metal layer 212. The motion eventually stops when the top metal layer 212 becomes coplanar with the top metal film 132 and the metal posts 40 at the top surface, but heat continues to be applied to the binding film 214 and the squeezed out adhesive 215, thereby converting the B-stage molten uncured epoxy into C-stage cured or hardened epoxy.

At this stage, the stacking structure 20 is bonded with sidewalls of the thermally conductive slug 10 and the metal posts 40 by the adhesive 215 squeezed out from the binding film 214. The binding film 214 as solidified provides a secure robust mechanical bond between the top metal layer 212 and the bottom metal layer 217. Accordingly, the thermally conductive slug 10 and the metal posts 40 are incorporated with a resin core 21 with the adhesive 215 sandwiched between the thermally conductive slug 10 and the resin core 21 and between the metal posts 40 and the resin core 21. The resin core 21 has a top side 201 bonded to the top metal layer 212 and a bottom side 202 bonded to the bottom metal layer 217.

FIG. 5 is a partial cross-sectional view of the structure after removal of excess adhesive that overflows onto the thermally conductive slug 10, the metal posts 40 and the top metal layer 212. The excess adhesive can be removed by lapping/grinding. After lapping/grinding, the thermally conductive slug 10, the metal posts 40, the top metal layer 212 and the adhesive 215 squeezed out from the binding film 214 are essentially coplanar with one another at a smoothed lapped/ground top surface.

FIG. 6 is a partial cross-sectional view of the structure after removal of the carrier film 31. The carrier film 31 is detached from the thermally conductive slug 10, the metal posts 40, the bottom metal layer 217 and the squeezed out adhesive 215 to expose the thermally conductive slug 10, the metal posts 40 and the bottom metal layer 217 from below. Accordingly, the adhesive 215 has exposed top and bottom surfaces essentially coplanar with the planar top and bottom sides 401, 402 of the metal posts 40, the planar top and bottom sides 101, 102 of the thermally conductive slug 10, and the planar outer surfaces of the top and bottom metal layers 212, 217 in the upward and downward directions, respectively.

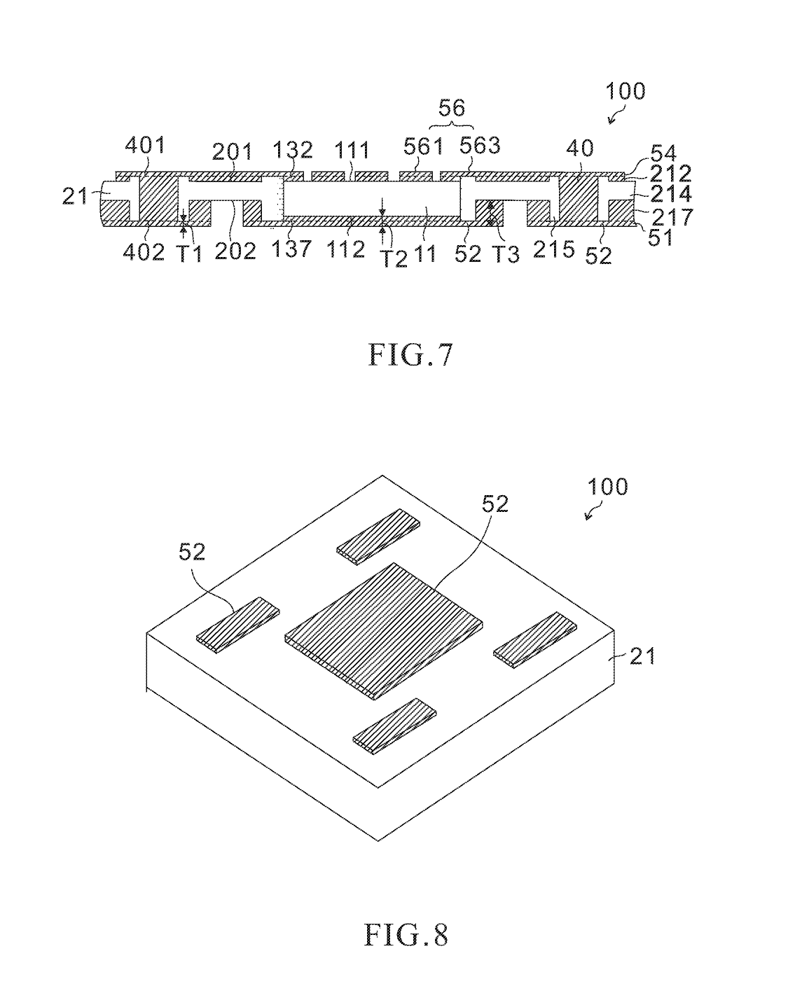

FIGS. 7, 8 and 9 are partial cross-sectional, bottom and top perspective views, respectively, of the structure provided with moisture inhibiting caps 52 and conductive traces 56. The bottom surface of the structure can be metallized to form a bottom plated layer 51 (typically a copper layer) as a single layer or multiple layers by numerous techniques, such as electroplating, electroless plating, evaporating, sputtering or their combinations. For instance, the structure can be first dipped in an activator solution to render the bottom surface of the structure catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper onto the bottom surface of the structure before depositing the electroplated copper layer on the seeding layer. After the deposition of the bottom plated layer 51, a metal patterning process is executed to form plural moisture inhibiting caps 52 spaced from each other. One of the moisture inhibiting caps 52, consisting of the bottom metal film 137, the bottom metal layer 217 and the bottom plated layer 51, includes a selected portion that laterally extends from the bottom metal film 137 underneath the electrical isolator 11 to the bottom metal layer 217 underneath the resin core 21, and the others of the moisture inhibiting caps 52, consisting of the bottom metal layer 217 and the bottom plated layer 51, each includes a selected portion that laterally extends from the bottom side 402 of the metal post 40 to the bottom metal layer 217 underneath the resin core 21. Specifically, the moisture inhibiting caps 52 have a first thickness T1 (about 0.5 to 50 microns) where it contacts the squeezed out adhesive 215, a second thickness T2 where it contacts the electrical isolator 11, a third thickness T3 where it contacts the resin core 21, and a flat surface that faces in the downward direction. In this illustration, the second thickness T2 and the third thickness T3 are larger than the first thickness T1, and the third thickness T3 is larger than the second thickness T2. The bottom metal film 137, the metal posts 40, the bottom metal layer 217 and the bottom plated layer 51 are shown as a single layer for convenience of illustration. The boundary (shown in dashed line) between the metal layers may be difficult or impossible to detect since copper is plated on copper. However, the boundary between the bottom plated layer 51 and the squeezed out adhesive 215 is clear.

Also, the top surface of the structure can be metallized to form a top plated layer 54 by the same activator solution, electroless copper seeding layer and electroplated copper layer. Once the desired thickness is achieved, a metal patterning process is executed to form the conductive traces 56 that include contact pads 561 and routing circuitries 563. The contact pads 561, consisting of the top plated layer 54 and the top metal film 132, laterally extend on the top side 111 of the electrical isolator 11, whereas the routing circuitries 563, consisting of the top plated layer 54, the top metal film 132 and the top metal layer 212, laterally extend on the top side 111 of the electrical isolator 11, the top side 201 of the resin core 21, the top side 401 of the metal posts 40 and the top surface of the adhesive 215 to contact and electrically connect the contact pads 561 and the metal posts 40. Also, the routing circuitries 563 completely cover the adhesive 215 between the metal posts 40 and the resin core 21 and interfaces between the metal posts 40 and the adhesive 215 from above. The contact pads 561 have a combined thickness of the top metal film 132 and the top plated layer 54 and can serve as electrical contacts for chip attachment. The routing circuitries 563 has a thickness of the top plated layer 54 (about 0.5 to 50 microns) where it contacts the squeezed out adhesive 215, a combined thickness of the top metal film 132 and the top plated layer 54 thereon where it contacts the electrical isolator 11, and a combined thickness of the top metal layer 212 and the top plated layer 54 thereon where it contacts the resin core 21. The routing circuitries 563 laterally extend from the contact pads 561 onto the resin core 21 and provide an electrical connection between the contact pads 561 and the metal posts 40. The metal patterning techniques include wet etching, electro-chemical etching, laser-assisted etching, and their combinations with etch masks (not shown) thereon that define the moisture inhibiting cap 52 and the conductive traces 56.

Accordingly, as shown in FIGS. 7, 8 and 9, a wiring board 100 is accomplished and includes an electrical isolator 11, metal posts 40, a resin core 21, a squeezed out adhesive 215, moisture inhibiting caps 52 and conductive traces 56. The resin core 21 covers and surrounds sidewalls of the electrical isolator 11 and the metal posts 40 and is mechanically connected to sidewalls of the electrical isolator 11 and the metal posts 40 by the squeezed out adhesive 215 between the electrical isolator 11 and the resin core 21 and between the metal posts 40 and the resin core 21. The moisture inhibiting caps 52 completely cover the adhesive 215 between the electrical isolator 11 and the resin core 21 and between the metal posts 40 and the resin core 21 as well as interfaces between the electrical isolator 11 and the adhesive 215 and between the metal posts 40 and the adhesive 215, and further laterally extend on the bottom side 202 of the resin core 21 from below. The conductive traces 56 laterally extend on the electrical isolator 11, the resin core 21, the metal posts 40 and the adhesive 215 from above to provide horizontal routing, and further are electrically coupled to the metal posts 40 that provide vertical routing. Also, the conductive traces 56 completely cover the adhesive 215 between the resin core 21 and the metal posts 40 and interfaces between the metal posts 40 and the adhesive 215 from above.

FIG. 10 is a cross-sectional view of a semiconductor assembly 110 with a semiconductor device 61 electrically connected to the wiring board 100 illustrated in FIG. 7. The semiconductor device 61, illustrated as a chip, is flip-chip mounted on the contact pads 561 of the wiring board 100 via solder bumps 71. Further, a lid 81 is mounted on the wiring board 100 to enclose the semiconductor device 61 therein from above. Accordingly, even if cracks are caused by mismatched CTE between the electrical isolator 11 and the adhesive 215 and between the metal posts 40 and the adhesive 215, the moisture inhibiting caps 52 of the wiring board 100 can restrict the passage of moisture through the cracks from ambiance into the interior of the semiconductor assembly 110. Additionally, the electrical isolator 11 can provide CTE-buffered contact interface for the semiconductor device 61, and the heat generated by the semiconductor device 61 can be transferred to the electrical isolator 11 and further spread out to the moisture inhibiting cap 52 underneath the electrical isolator 11.

### Embodiment 2

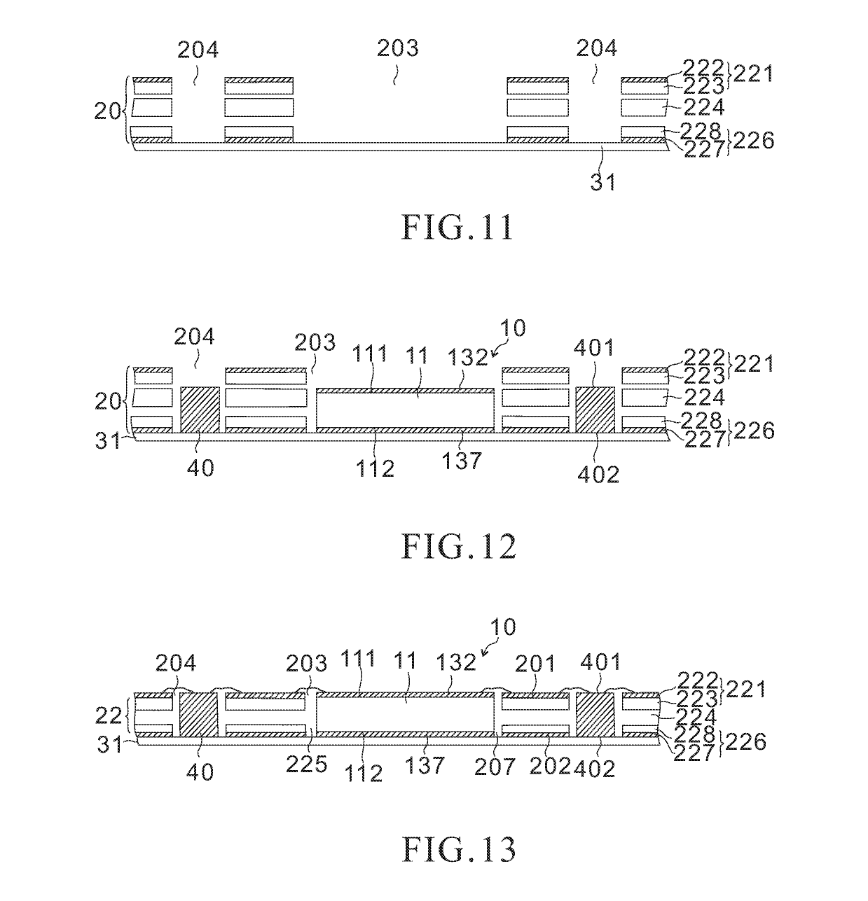

FIGS. 11-15 are schematic views showing another method of making a wiring board in which another stacking structure is provided to form a resin core in accordance with the second embodiment of the present invention.

For purposes of brevity, any description in Embodiment 1 above is incorporated herein insofar as the same is applicable, and the same description need not be repeated.

FIG. 11 is a partial cross-sectional view of the structure with a stacking structure 20 on a carrier film 31. The stacking structure 20 includes a first laminate substrate 221, a binding film 224 and a second laminate substrate 226. The stacking structure 20 has first and second apertures 203, 204 that extend through the first laminate substrate 221, the binding film 224 and the second laminate substrate 226. In this illustration, the first laminate substrate 221 includes a top metal layer 222 disposed on a first dielectric layer 223, and the second laminate substrate 226 includes a bottom metal layer 227 disposed on a second dielectric layer 228. The first and second dielectric layers 223, 228 typically are made of epoxy resin, glass-epoxy, polyimide or the like, and have a thickness of 50 microns. The top and bottom metal layers 222, 227 typically are made of copper and have a thickness of 35 microns. In this stacking structure 20, the binding film 224 is disposed between the first laminate substrate 221 and the second laminate substrate 226, and the top metal layer 222 of the first laminate substrate 221 and the bottom metal layer 227 of the second laminate substrate 226 respectively face in the upward and downward directions. By the adhesive property of the carrier film 31, the stacking structure 20 is attached to the carrier film 31 with the bottom metal layer 227 of the second laminate substrate 226 in contact with the carrier film 31.

FIG. 12 is a partial cross-sectional view of the structure with the thermally conductive slug 10 of FIG. 1 and metal posts 40 attached to the carrier film 31. The thermally conductive slug 10 is inserted into the first aperture 203 of the stacking structure 20, whereas the metal posts 40 are inserted into the second apertures 204 of the stacking structure 20. The thermally conductive slug 10 and the metal posts 40 are attached on the carrier film 31 with the outer surface of the bottom metal layer 137 and the bottom side 402 of the metal posts 40 facing towards the carrier film 31.

FIG. 13 is a partial cross-sectional view of the structure with an adhesive 225 squeezed out from the binding film 224 into gaps 207 between the thermally conductive slug 10 and the stacking structure 20 and between the metal posts 40 and the stacking structure 20. By applying heat and pressure, the binding film 224 is squeezed and part of the adhesive in the binding film 224 flows into the gaps 207. After the squeezed out adhesive 225 fills up the gaps 207, the binding film 224 and the squeezed out adhesive 225 are solidified. Accordingly, the thermally conductive slug 10 and the metal posts 40 are bonded to a resin core 22 by the squeezed out adhesive 225 in the gaps 207. In this illustration, the resin core 22 includes the first dielectric layer 223, the cured binding film 224 and the second dielectric layer 228, and has a top side 201 bonded to the top metal layer 222 and a bottom side 202 bonded to the bottom metal layer 227. The cured binding film 224 is integrated with the first dielectric layer 223 of the first laminate substrate 221 and the second dielectric layer 228 of the second laminate substrate 226, and provides secure robust mechanical bonds between the first laminate substrate 221 and the second laminate substrate 226. The squeezed out adhesive 225 in the gaps 207 provides secure robust mechanical bonds between the thermally conductive slug 10 and the resin core 22 and between the metal posts 40 and the resin core 22. The adhesive 225 squeezed out from the binding film 224 also rises slightly above the first and second apertures 203, 204 and overflows onto the top surfaces of the thermally conductive slug 10, the top metal layer 222 and the metal posts 40.

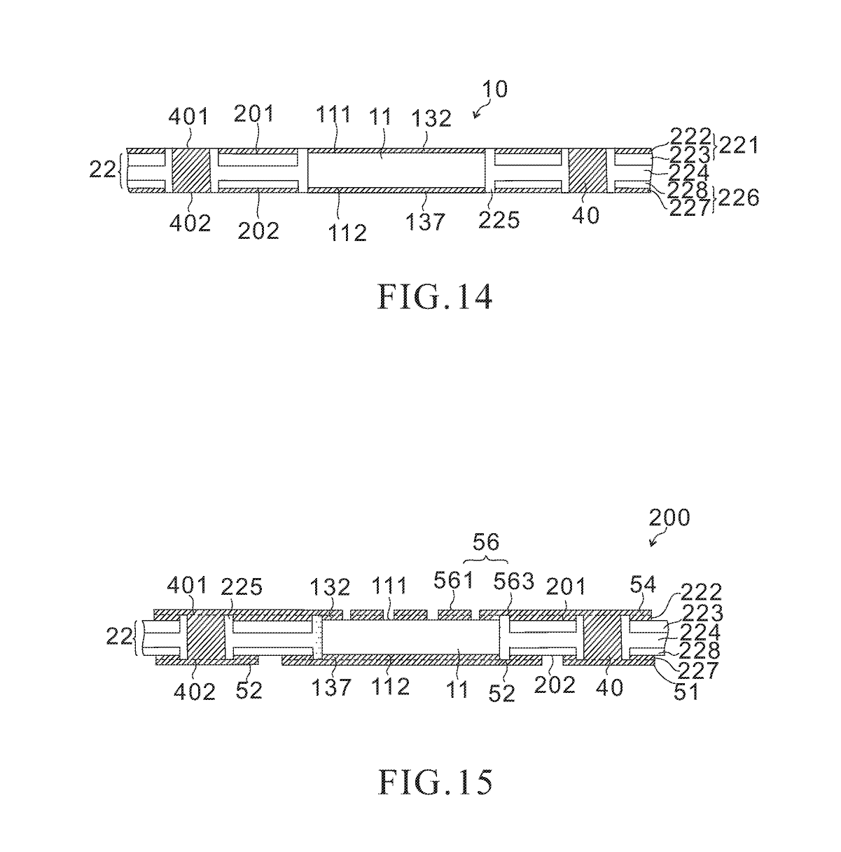

FIG. 14 is a partial cross-sectional view of the structure after removal of excess adhesive and the carrier film 31. The excess adhesive on the top metal film 132, the top metal layer 222 and the metal posts 40 is removed by lapping/grinding to create a smoothed lapped/ground top surface. The carrier film 31 is detached from the bottom metal film 137, the bottom metal layer 227, the metal posts 40 and the squeezed out adhesive 225 to expose the bottom metal film 137, the bottom metal layer 227 and the metal posts 40 from below. Accordingly, the adhesive 225 has exposed top and bottom surfaces essentially coplanar with the outer surfaces of the top and bottom metal films 132, 137, the top and bottom sides 401, 402 of the metal posts 40, and the outer surfaces of the top and bottom metal layers 222, 227 in the upward and downward directions, respectively.

FIG. 15 is a partial cross-sectional view of the structure provided with moisture inhibiting caps 52 and conductive traces 56. The moisture inhibiting caps 52 are formed by depositing a bottom plated layer 51, which is combined with the bottom metal film 137 and the bottom metal layer 227 from below, followed by a metal patterning process. Accordingly, the moisture inhibiting caps 52 include the bottom metal film 137, the bottom metal layer 227 and the bottom plated layer 51, and contacts and covers the electrical isolator 11, the resin core 22, the metal posts 40 and the squeezed out adhesive 225 from below. One of the moisture inhibiting caps 52 includes a selected portion that laterally extends from the bottom metal film 137 underneath the electrical isolator 11 to the bottom metal layer 227 underneath the resin core 22, and the others of the moisture inhibiting caps 52 each include a selected portion that laterally extends from the bottom side 402 of the metal post 40 to the bottom metal layer 227 underneath the resin core 22. Also, the top surface of the structure is metallized to form a top plated layer 54, followed by a metal patterning process to form the conductive traces 56. The conductive traces 56 contact and laterally extend on the top side 111 of the electrical isolator 11, the top side 201 of the resin core 22, the top side 401 of the metal posts 40, and the top surface of the adhesive 225 from above.

Accordingly, as shown in FIG. 15, a wiring board 200 is accomplished and includes an electrical isolator 11, metal posts 40, a resin core 22, a squeezed out adhesive 225, moisture inhibiting caps 52 and conductive traces 56. The resin core 22 is mechanically connected to the electrical isolator 11 and the metal posts 40 by the squeezed out adhesive 225. The moisture inhibiting caps 52 completely cover the adhesive 225 and interfaces between the electrical isolator 11 and the adhesive 225 and between the metal posts 40 and the adhesive 225 from below, and further laterally extend underneath the resin core 22. The conductive traces 56 include contact pads 561 on the top side 111 of the electrical isolator 11 and routing circuitries 563 electrically connecting the contact pads 561 and the metal posts 40 from above.

### Embodiment 3

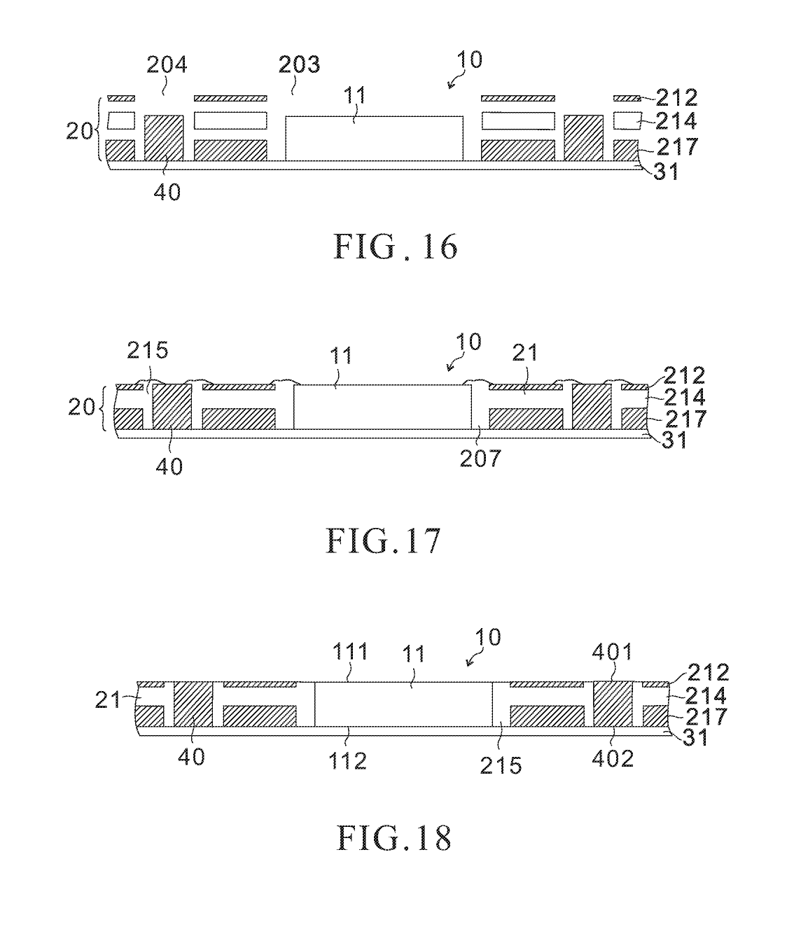

FIGS. 16-20 are schematic views showing yet another method of making a wiring board in which an electrical isolator with no metal films thereon is inserted into an aperture of the stacking structure in accordance with the third embodiment of the present invention.

For purposes of brevity, any description in the aforementioned Embodiments is incorporated herein insofar as the same is applicable, and the same description need not be repeated.

FIG. 16 is a partial cross-sectional view of the structure with a thermally conductive slug 10, a stacking structure 20 and metal posts 40 on a carrier film 31. The stacking structure 20 includes a top metal layer 212, a bottom metal layer 217, and a binding film 214 between the top metal layer 212 and the bottom metal layer 217. The thermally conductive slug 10 is inserted into the first aperture 203 of the stacking structure 20, whereas the metal posts 40 are inserted into the second apertures 204 of the stacking structure 20. In this embodiment, the thermally conductive slug 10 includes no metal films on the electrical isolator 11, and is attached on the carrier film 31 with the electrical isolator 11 in contact with the carrier film 31.

FIG. 17 is a partial cross-sectional view of the structure with an adhesive 215 squeezed out from the binding film 214 into gaps 207 between the thermally conductive slug 10 and the stacking structure 20 and between the metal posts 40 and the stacking structure 20. After the squeezed out adhesive 215 fills up the gaps 207, the binding film 214 and the squeezed out adhesive 215 are solidified. Accordingly, the thermally conductive slug 10 and the metal posts 40 are incorporated with a resin core 21 with the adhesive 215 sandwiched between the thermally conductive slug 10 and the resin core 21 and between the metal posts 40 and the resin core 21. In this illustration, the adhesive 215 squeezed out from the binding film 214 also rises slightly above the first and second apertures 203, 204 and overflows onto the top surfaces of the thermally conductive slug 10, the top metal layer 212 and the metal posts 40.

FIG. 18 is a partial cross-sectional view of the structure after removal of excess adhesive. The excess adhesive on the electrical isolator 11, the top metal layer 212 and the metal posts 40 is removed. Accordingly, the adhesive 215 has an exposed top surface essentially coplanar with the top side 111 of the electrical isolator 11, the outer surface of the top metal layer 212 and the top side 401 of the metal posts 40 in the upward direction.

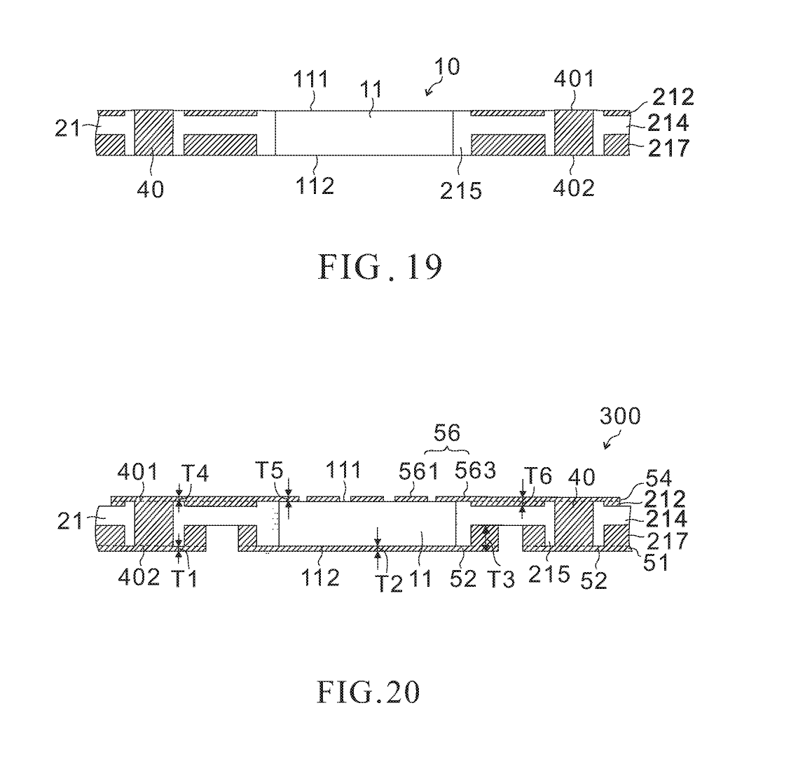

FIG. 19 is a partial cross-sectional view of the structure after removal of the carrier film 31. The carrier film 31 is detached from the thermally conductive slug 10, the metal posts 40, the bottom metal layer 217 and the squeezed out adhesive 215. Accordingly, the adhesive 215 has an exposed bottom surface essentially coplanar with the bottom side 112 of the electrical isolator 11, the bottom side 402 of the metal posts 40, and the outer surface of the bottom metal layer 217 in the downward direction.

FIG. 20 is a partial cross-sectional view of the structure provided with moisture inhibiting caps 52 and conductive traces 56. A bottom plated layer 51 is deposited typically by a sputtering process and then an electrolytic plating process to achieve desired thickness. Once the desired thickness is achieved, a metal patterning process is executed to form the moisture inhibiting caps 52. Accordingly, the moisture inhibiting caps 52 include the bottom metal layer 217 and the bottom plated layer 51, and contacts and covers the electrical isolator 11, the resin core 21, the metal posts 40 and the squeezed out adhesive 215 from below. One of the moisture inhibiting caps 52 includes a selected portion that laterally extends from the bottom side 112 of the electrical isolator 11 to the bottom metal layer 217 underneath the resin core 21, and the others of the moisture inhibiting caps 52 each include a selected portion that laterally extends from the bottom side 402 of the metal post 40 to the bottom metal layer 217 underneath the resin core 21. In this illustration, the moisture inhibiting caps 52 have a first thickness T1 (about 0.5 to 50 microns) where it contacts the squeezed out adhesive 215, a second thickness T2 where it contacts the electrical isolator 11 that is substantially equal to the first thickness T1, and a third thickness T3 where it contacts the resin core 21 that is larger than the first thickness T1 and the second thickness T2.

Also, a top plated layer 54 is deposited typically by a sputtering process and then an electrolytic plating process to achieve desired thickness. Once the desired thickness is achieved, a metal patterning process is executed to form the conductive traces 56. The conductive traces 56 contact and laterally extend on the electrical isolator 11, the resin core 21, the metal posts 40, and the adhesive 215 from above. In this illustration, the conductive traces 56 have a fourth thickness T4 (about 0.5 to 50 microns) where it contacts the squeezed out adhesive 215, a fifth thickness T5 where it contacts the electrical isolator 11 that is substantially equal to the fourth thickness T4, and a sixth thickness T6 where it contacts the resin core 21 that is larger than the fourth thickness T4 and the fifth thickness T5.

Accordingly, as shown in FIG. 20, a wiring board 300 is accomplished and includes an electrical isolator 11, metal posts 40, a resin core 21, a squeezed out adhesive 215, moisture inhibiting caps 52 and conductive traces 56. The resin core 21 is mechanically connected to the electrical isolator 11 and the metal posts 40 by the squeezed out adhesive 215. The moisture inhibiting caps 52 completely cover the adhesive 215 and interfaces between the electrical isolator 11 and the adhesive 215 and between the metal posts 40 and the adhesive 215 from below, and further laterally extend underneath the resin core 21. The conductive traces 56 include contact pads 561 on the top side 111 of the electrical isolator 11 and routing circuitries 563 electrically connecting the contact pads 561 and the metal posts 40 from above.

### Embodiment 4

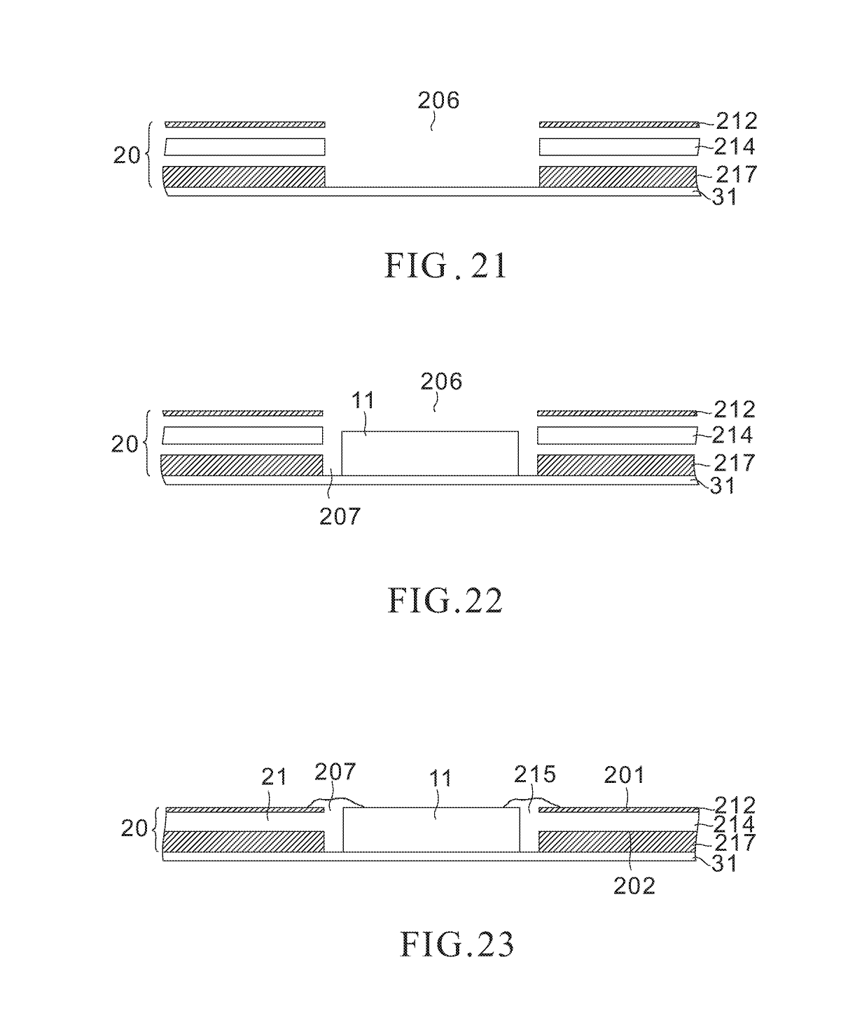

FIGS. 21-25 are schematic views showing a method of making a wiring board without metal posts in accordance with the fourth embodiment of the present invention.

For purposes of brevity, any description in the aforementioned Embodiments is incorporated herein insofar as the same is applicable, and the same description need not be repeated.

FIG. 21 is a partial cross-sectional view of the structure with a stacking structure 20 on a carrier film 31. The stacking structure 20 includes a top metal layer 212, a bottom metal layer 217, and a binding film 214 between the top metal layer 212 and the bottom metal layer 217. The stacking structure 20 has an aperture 206 that extends through the top metal layer 212, the binding film 214 and the bottom metal layer 217. By the adhesive property of the carrier film 31, the stacking structure 20 is attached to the carrier film 31 with the bottom metal layer 217 in contact with the carrier film 31.

FIG. 22 is a partial cross-sectional view of the structure with an electrical isolator 11 attached to the carrier film 31. The electrical isolator 11 is inserted into the aperture 206 of the stacking structure 20 and attached on the carrier film 31, leaving a gap 207 between the electrical isolator 11 and the stacking structure 20.

FIG. 23 is a partial cross-sectional view of the structure with an adhesive 215 squeezed out from the binding film 214 into the gap 207. After the squeezed out adhesive 215 fills up the gap 207, the binding film 214 and the squeezed out adhesive 215 are solidified. Accordingly, the electrical isolator 11 is bonded to a resin core 21 by the squeezed out adhesive 215 in the gap 207. The resin core 21 has a top side 201 bonded to the top metal layer 212 and a bottom side 202 bonded to the bottom metal layer 217. In this illustration, the adhesive 215 squeezed out from the binding film 214 also rises slightly above the aperture 206 and overflows onto the top surfaces of the electrical isolator 11 and the top metal layer 212.

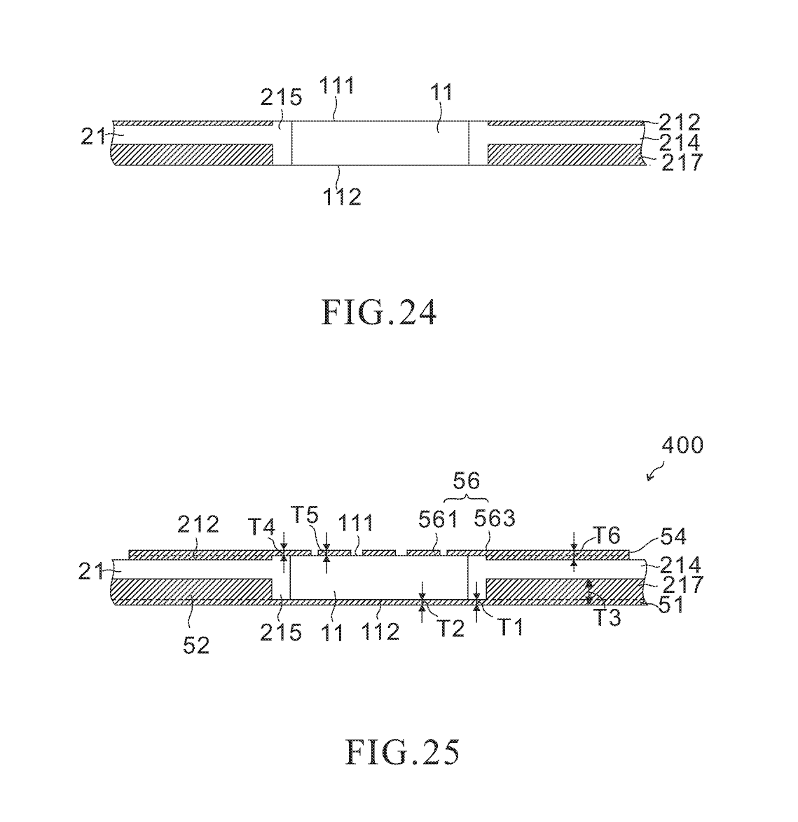

FIG. 24 is a partial cross-sectional view of the structure after removal of excess adhesive and the carrier film 31. The excess adhesive on the electrical isolator 11 and the top metal layer 212 is removed, and the carrier film 31 is detached therefrom. Accordingly, the adhesive 215 has exposed top and bottom surfaces essentially coplanar with the planar top and bottom sides 111, 112 of the electrical isolator 11 and the planar outer surfaces of the top and bottom metal layers 212, 217 in the upward and downward directions, respectively.

FIG. 25 is a partial cross-sectional view of the structure provided with a moisture inhibiting cap 52 and conductive traces 56. A bottom plated layer 51 is deposited typically by a sputtering process and then an electrolytic plating process to achieve desired thickness. Once the desired thickness is achieved, a metal patterning process is executed to form the moisture inhibiting cap 52. Accordingly, the moisture inhibiting cap 52 include the bottom metal layer 217 and the bottom plated layer 51, and contacts and covers the electrical isolator 11, the resin core 21 and the squeezed out adhesive 215 from below. The moisture inhibiting cap 52 includes a selected portion that laterally extends from the bottom side 112 of the electrical isolator 11 to the bottom metal layer 217 underneath the resin core 21. In this illustration, the moisture inhibiting cap 52 have a first thickness T1 (about 0.5 to 50 microns) where it contacts the squeezed out adhesive 215, a second thickness T2 where it contacts the electrical isolator 11 that is substantially equal to the first thickness T1, and a third thickness T3 where it contacts the resin core 21 that is larger than the first thickness T1 and the second thickness T2.

Also, a top plated layer 54 is deposited typically by a sputtering process and then an electrolytic plating process to achieve desired thickness. Once the desired thickness is achieved, a metal patterning process is executed to form the conductive traces 56. The conductive traces 56 contact and laterally extend on the electrical isolator 11, the resin core 21 and the adhesive 215 from above. In this illustration, the conductive traces 56 have a fourth thickness T4 (about 0.5 to 50 microns) where it contacts the squeezed out adhesive 215, a fifth thickness T5 where it contacts the electrical isolator 11 that is substantially equal to the fourth thickness T4, and a sixth thickness T6 where it contacts the resin core 21 that is larger than the fourth thickness T4 and the fifth thickness T5.

Accordingly, as shown in FIG. 25, a wiring board 400 is accomplished and includes an electrical isolator 11, a resin core 21, a squeezed out adhesive 215, a moisture inhibiting cap 52 and conductive traces 56. The resin core 21 is mechanically connected to the electrical isolator 11 by the squeezed out adhesive 215. The moisture inhibiting cap 52 completely covers the adhesive 215 and interfaces between the electrical isolator 11 and the adhesive 215 from below, and further laterally extend underneath the resin core 21. The conductive traces 56 include contact pads 561 on the top side 111 of the electrical isolator 11 and routing circuitries 563 laterally extending from the contact pads 561 onto the resin core 21.

As illustrated in the aforementioned embodiments, a distinctive wiring board is configured to have an electrical isolator and at least one moisture inhibiting cap and exhibit improved reliability. Preferably, the wiring board mainly includes an electrical isolator, a resin core, an adhesive, a moisture inhibiting cap and conductive traces, wherein (i) the electrical isolator has planar top and bottom sides; (ii) the resin core covers and surrounds sidewalls of the electrical isolator; (iii) the adhesive is sandwiched between the electrical isolator and the resin core; (iv) the moisture inhibiting cap laterally extends from the electrical isolator to the resin core, and completely covers a bottom surface of the adhesive; and (v) the conductive traces include contact pads and the routing circuitries, the contact pads laterally extending on the top side of the electrical isolator, and the routing circuitries laterally extending from the contact pads onto the resin core.

Optionally, the wiring board may further include metal posts, wherein (i) the metal posts each have planar top and bottom sides; (ii) the resin core also covers and surrounds sidewalls of the metal posts; (iii) the adhesive is also sandwiched between the metal posts and the resin core, and (iv) the routing circuitries electrically connect the contact pads and the metal posts.

The electrical isolator can provide a platform for chip attachment, whereas the optional metal posts can serve as signal vertical transduction pathway or provide ground/power plane for power delivery and return. Specifically, the electrical isolator is made of a thermally conductive and electrically insulating material and typically has high elastic modulus and low coefficient of thermal expansion (for example, 2×10⁻⁶ K⁻¹ to 10×10⁻⁶ K⁻¹). As a result, the electrical isolator, having CTE matching a semiconductor chip to be assembled thereon, provides a CTE-compensated contact interface for the semiconductor chip, and thus internal stresses caused by CTE mismatch can be largely compensated or reduced. Further, the electrical isolator also provides primary heat conduction for the chip so that the heat generated by the chip can be conducted away.

The resin core can be bonded to the electrical isolator and the optional metal posts by a lamination process. For instance, the electrical isolator may be first metallized by depositing top and bottom metal films (typically copper films) respectively on top and bottom sides of the electrical isolator to provide a thermally conductive slug having the electrical isolator and the top and bottom metal films, followed by inserting the thermally conductive slug and the optional metal posts respectively into first and second apertures of a stacking structure having a binding film disposed between a top metal layer and a bottom metal layer, and then applying heat and pressure in a lamination process to cure the binding film. As an alternative, the lamination process may be executed by inserting the electrical isolator with no top and bottom metal films thereon into the first aperture of the stacking structure and the optional metal posts into the second apertures of the stacking structure. By the lamination process, the binding film can provide a secure robust mechanical bond between the top metal layer and the bottom metal layer, and an adhesive squeezed out from the binding film covers and surrounds and conformally coats sidewalls of the thermally conductive slug and the optional metal posts. As a result, a resin core is formed to have top and bottom sides respectively bonded to the top and bottom metal layers (typically copper layers), and is adhered to the sidewalls of the thermally conductive slug and the optional metal posts by the squeezed out adhesive between the thermally conductive slug and the resin core and between the optional metal posts and the resin core. In the aspect of the thermally conductive slug having the top and bottom metal films, the adhesive preferably has a top surface substantially coplanar with the outer surface of the top metal film on the electrical isolator, the outer surface of the top metal layer on the resin core, and the top side of the optional metal posts, and a bottom surface substantially coplanar with the outer surface of the bottom metal film under the electrical isolator, the outer surface of the bottom metal layer under the resin core, and the bottom side of the optional metal posts. In another aspect of the thermally conductive slug having no top and bottom metal films, the adhesive preferably has a top surface substantially coplanar with the top side of the electrical isolator, the outer surface of the top metal layer on the resin core, and the top side of the optional metal posts, and a bottom surface substantially coplanar with the bottom side of the electrical isolator, the outer surface of the bottom metal layer under the resin core, and the bottom side of the optional metal posts.

Before the aforementioned lamination, a carrier film (typically an adhesive tape) may be used to provide temporary retention force. For instance, the carrier film can temporally adhere to the top or bottom side of the thermally conductive slug, the top or bottom side of the optional metal posts, and the top or bottom metal layer of the stacking structure to retain the thermally conductive slug and the metal posts within the first and second apertures of the stacking structure, respectively, followed by the lamination process of the stacking structure. After the electrical isolator and the optional metal posts are bonded with the resin core as mentioned above, the carrier film is detached therefrom before depositing the moisture inhibiting cap/the conductive traces.

The moisture inhibiting cap can be a metal layer (typically a copper layer) that completely covers interfaces between two mismatched CTE materials from the bottom sides of the electrical isolator and the resin core. The moisture inhibiting cap can contact and completely cover the bottom surface of the adhesive between the electrical isolator and the resin core as well as interfaces between the electrical isolator and the adhesive, and further laterally extend on the bottom side of the resin core. In the aspect of the thermally conductive slug having the top and bottom metal films, the moisture inhibiting cap can be formed by electroless plating followed by electrolytic plating to deposit a plated layer on the bottom surface of the adhesive, the outer surface of the bottom metal film under the electrical isolator, and the outer surface of the bottom metal layer under the resin core. As a result, the moisture inhibiting cap can include a selected portion that laterally extends from the bottom metal film under the electrical isolator to the bottom metal layer under the resin core. More specifically, the moisture inhibiting cap includes the bottom metal film under the electrical isolator and the bottom metal layer of the stacking structure, and have a first thickness (equal to the thickness of the plated layer in about 0.5 to 50 microns) where it contacts the adhesive, a second thickness (equal to the combined thickness of the plated layer and the bottom metal film) where it contacts the electrical isolator, a third thickness (equal to the combined thickness of the plated layer and the bottom metal layer) where it contacts the resin core, and a flat bottom surface. The second thickness and the third thickness are larger than the first thickness, and the second thickness may be equal to or different from the third thickness. As for the alternative aspect of using the electrical isolator with no metal film thereon in the lamination process, the moisture inhibiting cap preferably is formed by thin film sputtering followed by electrolytic plating to deposit a plated layer on the bottom surface of the adhesive, the bottom side of the electrical isolator, and the outer surface of the bottom metal layer under the resin core. As a result, the moisture inhibiting cap can include a selected portion that laterally extends from the bottom side of the electrical isolator to the bottom metal layer under the resin core. More specifically, the moisture inhibiting cap includes the bottom metal layer of the stacking structure, and have a first thickness (equal to the thickness of the plated layer in about 0.5 to 50 microns) where it contacts the adhesive, a second thickness where it contacts the electrical isolator that is substantially equal to the first thickness, a third thickness (equal to the combined thickness of the plated layer and the bottom metal layer) where it contacts the resin core that is larger than the first and second thickness, and a flat bottom surface. Likewise, for the wiring board with metal posts as vertical electrical connections, it is preferred to form additional moisture inhibiting caps each having a selected portion that laterally extends from the bottom side of the metal post to the bottom metal layer of the stacking structure. Accordingly, the wiring board can include plural moisture inhibiting caps spaced from each other to completely cover CTE mismatched interfaces. More specifically, the additional moisture caps can contact and completely cover the bottom surface of the adhesive between the metal posts and the resin core and interfaces between the metal posts and the adhesive and further laterally extend on the bottom side of the resin core. Other details regarding the additional moisture inhibiting caps are the same as those previously described for the moisture inhibiting cap, and are not repeated for purposes of clarity.

The conductive traces include contact pads on the top side of the electrical isolator and routing circuitries that laterally extend from the contact pads onto the resin core. Further, in the wiring board with the metal posts as vertical electrical connections, the conductive traces electrically connect the contact pads and the metal posts. More specifically, the routing circuitries have selected portions that laterally extend from the top side of the metal posts to the top side of the electrical isolator. As a result, the routing circuitries can contact and provide signal transmission between the metal posts and the contact pads, and also completely cover CTE mismatched interfaces around the top side of the metal posts. The contact pads can provide electrical contacts for semiconductor device connection, whereas the routing circuitries can provide horizontal routing and be electrically coupled to the metal posts that can serve as vertical electrical connections. The conductive traces can be formed by metal deposition and then metal patterning. For the aspect of the thermally conductive slug having top and bottom metal films, the conductive traces can be deposited by an electroless plating process and then an electrolytic plating process. Specifically, a plated layer can be deposited on and cover the top metal film on the electrical isolator, the top surface of the adhesive, the top metal layer on the resin core and the top side of the optional metal posts, followed by a patterning process to form the contact pads on the top side of the electrical isolator and the routing circuitries that laterally extend on the electrical isolator, the adhesive, the resin core and the metal posts from the top sides thereof. As a result, in this aspect, the contact pads have a combined thickness of the top metal film and the plated layer, and the routing circuitries have a thickness of the plated layer where it contacts the adhesive, a combined thickness of the top metal film and the plated layer where it contacts the electrical isolator, and a combined thickness of the top metal layer and the plated layer where it contacts the resin core. As for the alternative aspect of using the electrical isolator with no metal film thereon in the lamination process, the plated layer typically is formed by a sputtering process and then an electrolytic plating process and deposited on and cover the top side of the electrical isolator, the top surface of the adhesive, the top metal layer on the resin core and the top side of the optional metal posts. As a result, in the alternative aspect, the conductive traces have a thickness of the plated layer where it contacts the adhesive and the electrical isolator and a combined thickness of the top metal layer and the plated layer where it contacts the resin core. Further, in the wiring board with the metal posts as vertical electrical connections, the routing circuitries preferably completely cover the top surface of the adhesive between the metal posts and the resin core as well as interfaces between the metal posts and the adhesive and laterally extend to the contact pads and the metal posts and serve as moisture barriers to prevent passage of moisture through cracks at the interfaces.

The present invention also provides a semiconductor assembly in which a semiconductor device such as chip is mounted on the contact pads of the aforementioned wiring board. Specifically, the semiconductor device can be electrically connected to the wiring board using various using a wide variety of connection media including gold or solder bumps on the contact pads of the wiring board. Further, a lid can be provided to enclose the semiconductor device therein. Accordingly, even if cracks are generated at the interfaces between two mismatched CTE materials, the moisture inhibiting cap of the wiring board can restrict the passage of moisture through the cracks from ambiance into the interior of the semiconductor assembly. Further, the electrical isolator incorporated in the wiring board can provide CTE-matched contact interface for the semiconductor device, and the heat generated by the semiconductor device can be transferred to the electrical isolator and further spread out to the moisture inhibiting cap that is located underneath the electrical isolator and laterally extends beyond peripheral edges of the electrical isolator and has a larger thermal dissipation surface area than the electrical isolator.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction. For instance, in the position that the moisture inhibiting cap face the downward direction, the semiconductor device covers the electrical isolator in the upward direction regardless of whether another element such as the contact pad is between the semiconductor device and the electrical isolator.

The phrases “mounted on” and “attached on” include contact and non-contact with a single or multiple support element(s). For instance, the thermally conductive slug and the metal posts can be attached on the carrier film regardless of whether they contact the carrier film or are separated from the carrier film by an adhesive.

The phrases “electrical connection”, “electrically connected” and “electrically coupled” refer to direct and indirect electrical connection. For instance, the semiconductor device is electrically connected to the contact pads by the bumps but does not contact the contact pads.

The wiring board according to the present invention has numerous advantages. The electrical isolator provides CTE-compensated contact interface for chip attachment and also establish a heat dissipation pathway from the chip to the moisture inhibiting cap underneath the electrical isolator. The resin core provides mechanical support and serves as a spacer between the conductive traces and the moisture inhibiting caps and between the electrical isolator and the metal posts. The moisture inhibiting caps seal interfaces between the electrical isolator/metal posts and a surrounding plastic material and restricts the passage of moisture though cracks at the interfaces. The conductive traces provide horizontal electrical routing of the board, whereas the metal posts provide vertical electrical routing of the board. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a wiring board having a thermally conductive slug for chip attachment and moisture inhibiting caps incorporated therein, comprising steps of:
providing a thermally conductive slug having a planar top side and a planar bottom side, wherein the thermally conductive slug includes an electrical isolator;
providing metal posts each having a planar top side and a planar bottom side;
providing a stacking structure that includes a top metal layer and a bottom metal layer, a binding film disposed between the top metal layer and the bottom metal layer, a first aperture, and second apertures extending through the top metal layer, the binding film and the bottom metal layer, wherein the top and bottom metal layers each have a planar outer surface;
inserting the thermally conductive slug into the first aperture of the stacking structure and the metal posts into the second apertures of the stacking structure leaving gaps between the stacking structure and the thermally conductive slug and between the stacking structure and the metal posts, and then squeezing and curing the binding film to form a resin core that has a top side bonded to the top metal layer and a bottom side bonded to the bottom metal layer, wherein the stacking structure is adhered to sidewalls of the thermally conductive slug and the metal posts by an adhesive squeezed out from the binding film into the gaps between the stacking structure and the thermally conductive slug and between the stacking structure and the metal posts;
removing an excess portion of the squeezed out adhesive, such that the adhesive has exposed top and bottom surfaces substantially coplanar with the top and bottom sides of the thermally conductive slug, the outer surfaces of the top and bottom metal layers, and the top and bottom sides of the metal posts;
forming conductive traces that includes contact pads and routing circuitries, wherein the contact pads laterally extend on a top side of the electrical isolator, and the routing circuitries laterally extend from the contact pads onto the resin core and electrically connect the contact pads and the metal posts; and
forming moisture inhibiting caps that laterally extend from a bottom side of the electrical isolator to the bottom metal layer, and laterally extend from the bottom side of the metal posts to the bottom metal layer to completely cover the exposed bottom surface of the adhesive.

2. The method of claim 1, wherein the exposed top and bottom surfaces of the adhesive are substantially coplanar with the top and bottom sides of the electrical isolator, the outer surfaces of the top and bottom metal layers, and the top and bottom sides of the metal posts.

3. The method of claim 2, wherein the moisture inhibiting caps are metal layers and have selected portions formed by thin film sputtering followed by electrolytic plating and each has a thickness between 0.5 and 50 microns where it contacts the squeezed out adhesive and the electrical isolator.

4. The method of claim 1, wherein the thermally conductive slug further includes a top metal film and a bottom metal film respectively deposited on the top and bottom sides of the electrical isolator and each having a planar outer surface, and the exposed top and bottom surfaces of the adhesive are substantially coplanar with the outer surfaces of the top and bottom metal films, the outer surfaces of the top and bottom metal layers, and the top and bottom sides of the metal posts.

5. The method of claim 4, wherein the moisture inhibiting caps are metal layers and have selected portions formed by electroless plating followed by electrolytic plating and each has a thickness between 0.5 and 50 microns where it contacts the squeezed out adhesive.

6. A method of making a wiring board having an electrical isolator and a moisture inhibiting cap incorporated therein, comprising steps of:
providing an electrical isolator having a planar top side and a planar bottom side;
providing a stacking structure that includes a top metal layer and a bottom metal layer, a binding film disposed between the top metal layer and the bottom metal layer, and an aperture extending through the top metal layer, the binding film and the bottom metal layer, wherein the top and bottom metal layers each have a planar outer surface;
inserting the electrical isolator into the aperture of the stacking structure leaving a gap between the stacking structure and the electrical isolator, and then squeezing and curing the binding film to form a resin core that has a top side bonded to the top metal layer and a bottom side bonded to the bottom metal layer, wherein the stacking structure is adhered to sidewalls of the electrical isolator by an adhesive squeezed out from the binding film into the gap between the stacking structure and the electrical isolator;
removing an excess portion of the squeezed out adhesive, such that the adhesive has exposed top and bottom surfaces substantially coplanar with the top and bottom sides of the electrical isolator and the outer surfaces of the top and bottom metal layers;
forming conductive traces that includes contact pads and routing circuitries, wherein the contact pads laterally extend on the top side of the electrical isolator, and the routing circuitries laterally extend from the contact pads onto the resin core; and
forming a moisture inhibiting cap that laterally extends from the bottom side of the electrical isolator to the bottom metal layer to completely cover the exposed bottom surface of the adhesive.

7. The method of claim 6, wherein the moisture inhibiting cap is a metal layer and has selected portions formed by thin film sputtering followed by electrolytic plating and each has a thickness between 0.5 and 50 microns where it contacts the squeezed out adhesive and the electrical isolator.

8. A semiconductor assembly, comprising:
a wiring board, including:
an electrical isolator that has a planar top side and a planar bottom side;
a resin core that covers and surrounds sidewalls of the electrical isolator;
an adhesive that is sandwiched between the electrical isolator and the resin core;
a moisture inhibiting cap that completely covers a bottom surface of the adhesive and has a first thickness where it contacts the adhesive, a second thickness where it contacts the electrical isolator that is substantially equal to the first thickness, and a third thickness where it contacts the resin core that is larger than the first thickness and the second thickness; and
conductive traces that include contact pads and routing circuitries and have a fourth thickness where they contact the adhesive, a fifth thickness where they contact the electrical isolator that is substantially equal to the fourth thickness, and a fifth thickness where they contact the resin core that is larger than the fourth thickness and the fifth thickness, wherein the contact pads laterally extend on the top side of the electrical isolator, and the routing circuitries laterally extend from the contact pads onto the resin core; and
a semiconductor device that is mounted to and electrically connected to the contact pads.

9. The semiconductor assembly of claim 8, wherein the moisture inhibiting cap is a metal layer and the first thickness and the second thickness are between 0.5 and 50 microns.

10. The semiconductor assembly of claim 8, wherein (i) the wiring board further includes metal posts each having a planar top side and a planar bottom side, (ii) the resin core also covers and surrounds sidewalls of the metal posts, (iii) the adhesive is also sandwiched between the metal posts and the resin core, and (iv) the routing circuitries electrically connect the contact pads and the metal posts.

11. The semiconductor assembly of claim 10, wherein the wiring board further includes additional moisture inhibiting caps that completely cover a bottom surface of the adhesive between the metal posts and the resin core.
